(19) United States
(12) Patent Application Publication
(10) Pub. No.: US 2012/0085730 A1
(43) Pub. Date: Apr. 12, 2012

(54) METHOD OF MANUFACTURING WIRING BOARD

(75) Inventors: Shinya SASAKI, Kawasaki (JP); Motoaki TANI, Kawasaki (JP)

(73) Assignee: FUJITSU LIMITED, Kawasaki-shi (JP)

(21) Appl. No.: 13/326,839

(22) Filed: Dec. 15, 2011

Related U.S. Application Data
(63) Continuation of application No. PCT/JP2009/002884, filed on Jun. 24, 2009.

(51) Int. Cl. H05K 3/46

(52) U.S. Cl. 216/13; 427/97.4

(57) ABSTRACT

A method for manufacturing a wiring board, includes: forming an insulating resin layer on a conductive layer; forming a metal chloride or a metal sulfate on the insulating resin layer; forming a protective layer on the metal chloride or the metal sulfate; forming an exposed portion in the insulating resin layer, the metal chloride or the metal sulfate, and the protective layer so as to at least partially expose the conductive layer; removing residues in the exposed portion; removing the protective layer; and forming a wiring on the insulating resin layer in which the protective layer has been removed.

### CROSS-REFERENCE TO RELATED APPLICATIONS

This is a continuation of International Application No. PCT/JP2009/002884 filed on Jun. 24, 2009, the entire contents of which are incorporated herein by reference.

### BACKGROUND

1. Field

Embodiments relate to a method of manufacturing a wiring board.

2. Background

For a printed wiring board having a multilayer wiring structure produced by a build-up process, for example, a build-up board, insulating resin layers are formed between a plurality of wiring layers, and minute holes for establishing electrical continuity between the plural wiring layers, for example, via holes, are formed in the insulating layers. For example, the via holes may be formed with a laser. When the via holes are formed with the laser, resin residues left on the bottom of the via holes, for example, smears are removed using a chemical solution of, for example, potassium permanganate, or using a plasma (desmear treatment).

The related art is disclosed in Japanese Laid-open Patent Publication No. 2004-235202.

### SUMMARY

According to one aspect of the embodiments, a method of manufacturing a wiring board, includes: forming an insulating resin layer on a conductive layer; forming a metal chloride or a metal sulfate on the insulating resin layer; forming a protective layer on the metal chloride or the metal sulfate; forming an exposed portion in the insulating resin layer, the metal chloride or the metal sulfate, and the protective layer so as to at least partially expose the conductive layer; removing residues in the exposed portion; removing the protective layer; and forming a wiring on the insulating resin layer in which the protective layer has been removed.

Additional advantages and novel features of the invention will be set forth in part in the description that follows, and in part will become more apparent to those skilled in the art upon examination of the following or upon learning by practice of the invention.

### BRIEF DESCRIPTION OF DRAWINGS

FIGS. 1A to 1L illustrate an exemplary manufacturing method of a wiring board.

FIGS. 2A to 2F illustrate an exemplary manufacturing method of a wiring board.

### DESCRIPTION OF EMBODIMENTS

Fine wiring may be formed by a semi-additive method for forming wiring. An opening is formed in an insulating resin layer, and then desmear treatment is performed. After the desmear treatment, the insulating resin layer and the opening are subjected to electroless plating. A reverse pattern of a wiring pattern is formed with a dry film resist. Electroplating is performed on the resulting electroless plating film to remove the reverse pattern and the electroless plating film below the reverse pattern, thereby forming wiring. The surface of the insulating resin layer may be roughened by the desmear treatment. When a wiring layer whose line and space (L/S) is 10 μm/10 μm or less is formed by the semi-additive method for forming wiring, laser light may be diffusely reflected during exposure of the dry film resist, thereby failing to a desired resist pattern or wiring shape.

To protect the surface of the insulating resin layer from the desmear treatment, after the formation of a metal layer on the insulating resin layer, an opening may be formed with a laser, and then desmear treatment may be performed. Since Laser power is high for processing the metal layer at the time of the formation of via holes, each of the via holes may not have a small diameter.

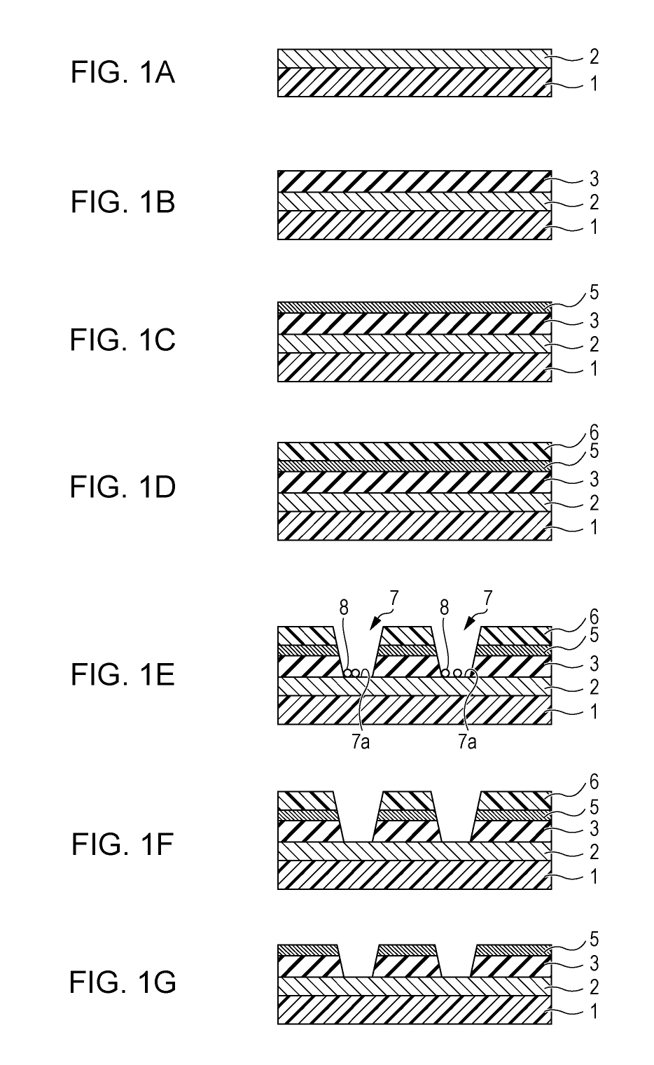

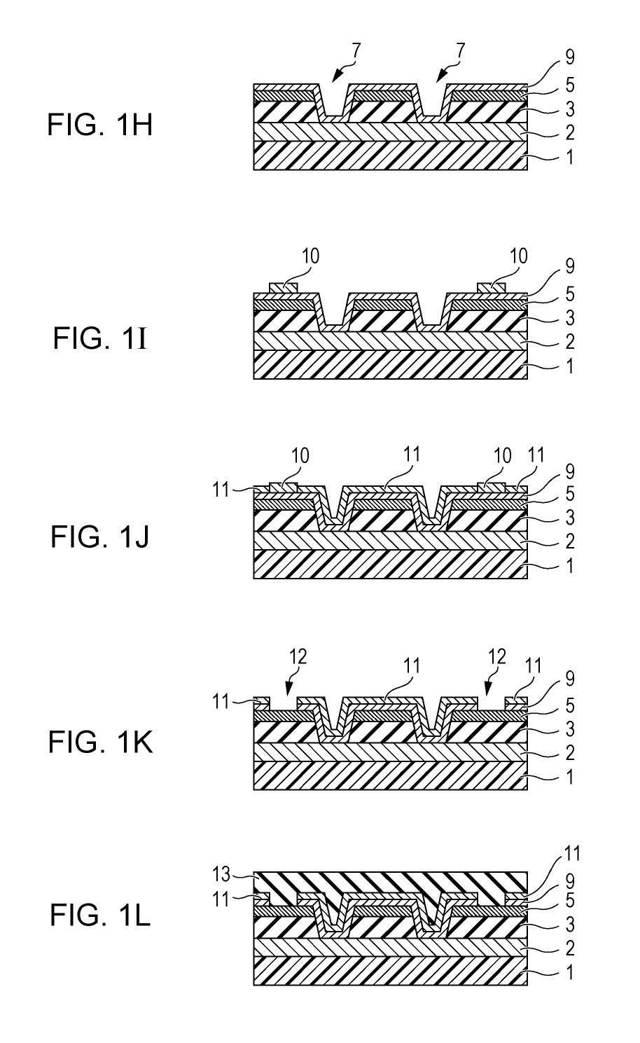

FIGS. 1A to 1L illustrate an exemplary manufacturing method of a wiring board. The wiring board may be a multilayer wiring board.

As illustrated in FIG. 1A, a first wiring 2 is formed on a substrate 1. The substrate 1 may be a glass fiber reinforced resin substrate. The glass fiber reinforced resin substrate may include, for example, a conductive wiring. A circuit may be formed on the glass fiber reinforced resin substrate by a known technique. In FIGS. 1A to 1L, the patterned first wiring 2 may not be depicted. For example, copper or an alloy containing copper may be used as the conductive wiring.

As illustrated in FIG. 1B, a first insulating layer 3 is formed on the first wiring 2. The first insulating layer 3 may be an insulating film between wiring layers on a multilayer wiring board. The first insulating layer 3 may include, for example, an insulating organic resin. For example, an insulating epoxy resin may be used as a material for the first insulating layer 3. To form the first insulating layer 3, for example, a film-like epoxy resin may be bonded to the substrate with a laminator. Alternatively, a liquid resin applied to the substrate may be cured by, for example, heat or light.

As illustrated FIG. 1C, a separating layer 5 including a metal chloride and/or a metal sulfate is formed on the first insulating layer 3. A protective layer 6 is formed on the separating layer 5. The protective layer 6 may be removed. The separating layer 5 may be formed in order to selectively remove the protective layer 6 from the first insulating layer 3. The substrate may be immersed in a solvent which dissolves the protective layer 6 and which does not dissolve the separating layer 5 and first insulating layer 3, thereby removing the protective layer 6. The substrate may be immersed in an etchant that etches the separating layer 5, thereby separating the protective layer 6 together with the separating layer 5 from the first insulating layer 3. Examples of the metal chloride that may be used include chlorides containing tin (Sn), palladium (Pd), or silver (Ag). Examples of the metal sulfate that may be used include sulfates containing tin (Sn), palladium (Pd), or silver (Ag). A chloride or a sulfate, e.g., SnCl₂, PdCl₂, or PdSO₄, is used as a catalyst at the time of electroless plating and thus may increase the conductivity between layers of a multilayer wiring board. For example, the substrate 1 including the first insulating layer 3 may be immersed in a colloidal solution including a metal chloride and/or a metal sulfate, rinsed with water, and dried to form the separating layer 5 on the first insulating layer 3. The separating layer 5 may have a thickness of, for example, about 5 nm to about 50 nm.

As illustrated in FIG. 1D, the protective layer 6 is formed on the separating layer 5 including the metal chloride and/or the metal sulfate. The protective layer 6 may reduce the degree of etching of the upper surface of the first insulating layer 3 during desmear treatment. As a material for the protective layer 6, an organic resin is used. The material used in the protective layer 6 includes the organic resin that is substantially identical or similar to the organic resin contained in the first insulating layer 3. Therefore, a narrow opening, for example, a narrow exposed portion, may be formed. When the protective layer 6 includes, for example, a metal, the protective layer 6 may be irradiated with laser light having relatively high power at the time of the formation of the opening in order to remove the protective layer 6. Since energy is applied to the first insulating layer 3, which is a lower layer, during the irradiation, an opening having a small diameter may not be formed. A carbon dioxide laser with high productivity may not be used. When the protective layer 6 is removed from the first insulating layer 3 by immersing the substrate in a separation liquid which dissolves the protective layer 6 and which does not dissolve the first insulating layer 3 or the separating layer 5, the solubility of the protective layer 6 in the separation liquid may be higher than that of the first insulating layer 3 in the separation liquid. When the material used in the first insulating layer 3 includes an epoxy resin, for example, an acrylic resin may be used as a material for the protective layer 6. To form the protective layer 6 including the organic resin, for example, a dry film resist including a film-like acrylic resin and a photosensitizer may be bonded to the substrate with a laminator. The bonded resist may be exposed. Alternatively, a liquid resin applied to the substrate may be cured by, for example, heat or light.

As illustrated in FIG. 1E, portions of the protective layer 6, the separating layer 5, and the first insulating layer 3 to be formed into via holes are irradiated with laser light to remove the portions of the protective layer 6, the separating layer 5, and the first insulating layer 3, thereby forming openings 7, for example, exposed portions. The resulting carbonized or melted resin that was not evaporated or scattered may be left as smears (residues) 8 on bottoms 7a of the openings 7. Examples of a laser that may be used to form the openings 7 may include carbon dioxide lasers, UV-YAG lasers, and excimer lasers. A carbon dioxide laser with high productivity may be used. For example, when the first insulating layer 3 has a thickness of about 40 μm, the openings 7 each having a diameter of about 30 μm to about 100 μm may be formed. When the first insulating layer 3 has a thickness of about 40 μm and the protective layer 6 and the separating layer 5 are not formed, each of the openings 7 may have a diameter of about 50 μm at a minimum.

As illustrated in FIG. 1F, the smears 8 left on the bottoms 7a of the openings 7 are removed (desmear treatment). Dry etching, e.g., plasma etching or reactive ion etching, or wet etching using a solution including permanganate may be performed. For the plasma etching, target objects, e.g., the smears 8, are etched using excited species, e.g., excited molecules, radicals, or ions which are generated by molecular dissociation due to plasma discharge. The etching is performed by evaporation of a volatile compound generated by reaction of the excited species and the smears 8. The plasma etching may be performed in an atmosphere of oxygen, nitrogen, or a mixed gas of oxygen and nitrogen. For the reactive ion etching, in a plasma state in which radio frequency power, for example, radio frequency power at 13.56 MHz, is applied to a reactive gas, e.g., CF₄ or SF₆, the smears 8 are bombarded with accelerated positive ions, thereby removing the smears 8.

As illustrated in FIG. 1G, the protective layer 6 is removed. For example, the protective layer 6 is removed with a separation liquid which dissolves the protective layer 6 and which does not dissolve the first insulating layer 3. Examples of the separation liquid that may be used include organic amine-based separation liquids and aqueous solutions of sodium hydroxide. Examples of the organic amine-based separation liquids that may be used include RS-2000 (trade name, manufactured by Atotech Deutschland GmbH), R-100 (trade name, manufactured by Mitsubishi Gas Chemical Company, Inc.), HTO (trade name, manufactured by Nichigo-Morton Co., Ltd). After the removal of the protective layer 6, the separating layer 5 may be left on the first insulating layer 3. The ten-point height of irregularities Rz of the first insulating layer 3 may be substantially identical or similar to the ten-point height of irregularities Rz of the first insulating layer 3 after the formation of the first insulating layer 3 and may be, for example, about 0.2 μm.

When the surface roughness of the separating layer 5 after the removal of the protective layer 6 is substantially identical or similar to the surface roughness of the first insulating layer 3 after the formation of the first insulating layer 3, part of the protective layer 6 may be left on the surface of the separating layer 5. When the protective layer 6 is removed, the protective layer 6 may be removed from the first insulating layer 3 together with the separating layer 5 using the etchant that etches the separating layer 5. Examples of the etchant that may be used include cyan-, iodine-, and nitric acid-based separation liquids that dissolve Sn and Pd. An example of the cyan-based separation liquid that may be used is Hakurex (trade name, manufactured by Electroplating Engineers of Japan Ltd). An example of the iodine-based separation liquid that may be used is PD-280 (trade name, manufactured by Daiwa Fine Chemicals Co., Ltd). An example of the nitric acid-based separation liquid that may be used is FINELISE PJ-10 (trade name, manufactured by Ebara-Udylite Co., Ltd).

As illustrated in FIG. 1H, a seed layer 9 is formed on the first insulating layer 3 and inside the openings 7. The seed layer 9 may be formed by, for example, electroless plating. The seed layer 9 may include, for example, an elemental metal, e.g., copper or nickel, or an alloy containing at least one of copper and nickel. The seed layer 9 may have a thickness of, for example, 0.1 μm to 5 μm.

As illustrated in FIG. 1I, a resist pattern 10 is formed on the first insulating layer 3. For example, a photoresist is applied to the seed layer 9. The photoresist is exposed through a photomask including an opening pattern corresponding to the resist pattern 10. Developing is performed to form the resist pattern 10. Since the first insulating layer 3 has low surface roughness after desmear treatment, the degree of diffuse reflection may be reduced at the time of the exposure of the photoresist. Accordingly, the line and space (L/S) of the resist pattern 10 may be reduced.

As illustrated in FIG. 1J, copper plating is performed on the surface of a portion of the seed layer 9 on which the resist pattern 10 is not arranged, thereby forming a conductive layer corresponding to a second wiring 11. As illustrated in FIG. 1K, the resist pattern 10 is removed with a resist-separating liquid. The seed layer 9 is removed by etching to form the second wiring 11 and openings 12.

As illustrated in FIG. 1L, a second insulating layer 13 is formed on the second wiring 11 and inside the openings 12. These processes from the formation of the separating layer 5 to the formation of the second wiring 11 may be repeated to form a multilayer wiring board having a three or more layer structure.

In the manufacturing method of a wiring board illustrated in FIGS. 1A to 1L, the degree of diffuse reflection of exposure light irradiated to the resist at the time of the formation of the resist pattern 10 is reduced because of the low surface roughness of the first insulating layer 3 after the desmear treatment. Thus, the L/S of the second wiring 11 arranged on the first insulating layer 3 may be reduced. Since energy applied to the first insulating layer 3 during the formation of the via holes is reduced, each of the resulting via holes may have a small diameter.

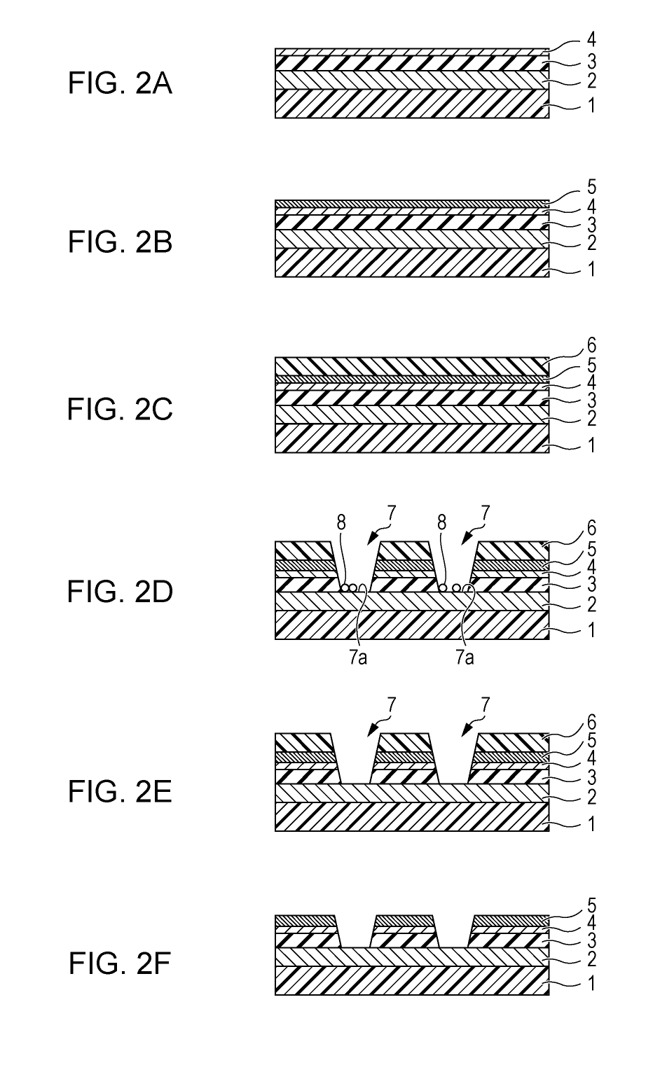

FIGS. 2A to 2F illustrate an exemplary manufacturing method of a wiring board. Descriptions substantially identical or similar to those of the manufacturing method illustrated in FIGS. 1A to 1L may be omitted or reduced.

Similarly to the method for manufacturing a wiring board illustrated in FIGS. 1A to 1L, the first wiring 2 and the first insulating layer 3 are formed on the substrate 1. As illustrated in FIG. 2A, an adhesion layer 4 is formed on the first insulating layer 3. The adhesion layer 4 improves the adhesion between the first insulating layer 3 and the second wiring 11 formed on the first insulating layer 3. Thus, the reliability of the wiring in a multilayer wiring board may be improved.

For example, the adhesion layer 4 may include at least one metal selected from zinc, nickel, cobalt, and chromium, or at least one compound selected from triazinethiol, a silane coupling agent, nitrobenzoic acid, and mercaptosulfonic acid. As the triazinethiol, a material in which two or more mercapto groups are attached to a triazine ring, for example, triazinetrithiol, may be used. The silane coupling agent may include, in its molecule, at least one selected from amino, mercapto, epoxy, imidazolyl, vinyl, dialkylamino, and pyridyl groups. Examples of the nitrobenzoic acid that may be used include nitrobenzoic acid, nitrophthalic acid, nitrosalicylic acid, and alkali metal salts thereof. Examples of the mercaptosulfonic acid that may be used include mercaptoethanesulfonic acid, mercaptopropanesulfonic acid, and alkali metal salts thereof.

For example, the adhesion layer 4 is formed on the first insulating layer 3. A surface of metal foil, such as copper foil, is subjected to chromate treatment to form a layer including at least one selected from zinc, nickel, cobalt, and chromium on the surface of the metal foil. The layer formed by the chromate treatment is transferred from the metal foil to the first insulating layer 3, thereby forming the adhesion layer 4 containing the metal. For example, the adhesion layer 4 containing a compound is formed on the first insulating layer 3 by immersing the substrate 1 including the first insulating layer 3 in an aqueous solution containing the compound described above. The adhesion layer 4 may have a thickness of, for example, about 1 nm to about 10 nm.

The adhesion layer 4 may include a plurality of sublayers. For example, the adhesion layer 4 may include a compound-containing sublayer and a metal-containing sublayer arranged thereon.

As illustrated in FIG. 2B, the separating layer 5 including a metal chloride and/or a metal sulfate is formed on the adhesion layer 4. The separating layer 5 may be substantially the same as the separating layer 5 illustrated in FIG. 1C, and redundant description may be omitted or reduced.

As illustrated in FIG. 2C, the protective layer 6 is formed. The protective layer 6 may be substantially the same as the protective layer 6 illustrated in FIG. 1D, and redundant description may be omitted or reduced.

As illustrated in FIG. 2D, portions of the protective layer 6, the separating layer 5, the adhesion layer 4, and the first insulating layer 3 to be formed into vias are irradiated with laser light, thereby forming the openings 7. The resulting carbonized or melted resin that was not evaporated or scattered may be left as the smears (residues) 8 on the bottoms 7a of the openings 7.

As illustrated in FIG. 2E, the smears 8 left on the bottoms 7a of the openings 7 are removed (desmear treatment). As illustrated in FIG. 2F, the protective layer 6 is removed. The desmear treatment may be substantially the same as the desmear treatment illustrated in FIG. 1F. The removal of the protective layer 6 may be substantially the same as the removal of the protective layer 6 illustrated in FIG. 1G.

The processes illustrated in FIGS. 2A to 2F may be repeated to form a multilayer wiring board having a three- or more layer structure.

The L/S of the second wiring 11 arranged on the first insulating layer 3 becomes small, and the multilayer wiring board including the via holes each having a small diameter is formed. The presence of the adhesion layer 4 improves the adhesion between the first insulating layer 3 and the separating layer 5 and between the second wiring 11 and the first insulating layer 3, thereby improving the reliability in the wiring of the multilayer wiring board.

For example, a thermosetting epoxy resin is laminated as a first insulating layer on a substrate including first wiring that contains copper. The first insulating layer is cured by heating at about 180° C. for about 1 hour. The first insulating layer may have a thickness of about 40 μm. The substrate including the first insulating layer is immersed in a Sn—Pd colloidal liquid, e.g., Cataposit 44 (trade name, manufactured by Rohm and Haas Company) at about 40° C. for about 5 minutes and then rinsed with water. The substrate is dried at about 120° C. to form a separating layer including tin chloride and palladium chloride. A dry film resist composed of an acrylic resin, for example, RY3325 (trade name, manufactured by Hitachi Chemical Company, Ltd.), which will serve as a protective layer, is laminated on the layer including tin chloride and palladium chloride. The resist may have a thickness of about 25 μm. The resist is irradiated with light having a wavelength of about 365 nm at about 200 mJ/cm². Portions of the protective layer, the layer including tin chloride and palladium chloride, and the first insulating layer to be formed into a via hole are irradiated with carbon dioxide laser light to form an opening having a diameter of about 70 μm. Plasma treatment (desmear treatment) is performed with a mixed gas of oxygen and CF₄ in a mixing ratio of about 95:5 to remove smears left on the bottom of the opening. The substrate is immersed in an amine-based separation liquid for a dry film, for example, RS-2000 (trade name, manufactured by Atotech Deutschland GmbH), to remove the protective layer. After the removal of the protective layer, the ten-point height of irregularities Rz of an upper surface of the substrate may be about 0.2 μm. The separating layer arranged above the upper surface of the substrate may have a thickness of about 5 nm to about 50 nm. The measured ten-point height of irregularities of the upper surface of the substrate may suggest the value of the first insulating layer below the separating layer. Electroless plating is performed with an electroless plating solution manufactured by Rohm and Haas Company, thereby forming a copper-including seed layer inside the opening and on the layer including tin chloride and palladium chloride. The seed layer may have a thickness of about 0.3 μm. A line-and-space (L/S) resist pattern is formed on the seed layer by photolithography with a dry film resist, for example, RY3215 (trade name, manufactured by Hitachi Chemical Company, Ltd.) having a thickness of about 15 μm. The L/S of the resist pattern may be about 10 μm/about 10 μm. Electroplating is performed on the seed layer to form a copper-containing conductive layer serving as second wiring. The conductive layer may have a thickness of about 15 μm. The resist pattern is removed. The seed layer below the resist pattern that has been removed is removed, thereby forming the second wiring. The L/S of the second wiring may be about 10 μm/about 10 μm. The second wiring may have a thickness of about 15 μm.

A thermosetting epoxy resin to be used as a first insulating layer is laminated on a substrate on which the first wiring including copper is provided. The first insulating layer is cured by heating at about 180° C. for about 1 hour. The first insulating layer may have a thickness of about 40 μm. A portion of the first insulating layer to be formed into a via is irradiated with carbon dioxide laser light to form an opening having a diameter of about 70 μm. Plasma treatment (desmear treatment) is performed with a mixed gas of oxygen and CF₄ in a mixing ratio of about 95:5 to remove smears left on the bottom of the laser via. After the desmear treatment, the ten-point height of irregularities Rz of the first insulating layer may be about 2 μm. Electroless plating is performed with an electroless plating solution manufactured by Rohm and Haas Company, thereby forming a seed layer inside the opening and on the first insulating layer, the seed layer including copper and having a thickness of about 0.3 μm. A resist pattern having an L/S of about 10 μm/about 10 μm is formed on the seed layer by photolithography with a dry film resist, for example, RY3215 (trade name, manufactured by Hitachi Chemical Company, Ltd.) having a thickness of about 15 μm. Residues of the resist may be observed on a portion of the seed layer where second wiring will be formed. A copper-containing conductive layer serving as second wiring is formed by electroplating. The L/S of the copper-containing conductive layer may not be about 10 μm/about 10 μm.

A thermosetting epoxy resin to be used as a first insulating layer is laminated on a substrate on which the first wiring including copper is provided. The first insulating layer may have a thickness of about 40 μm. Rolled copper foil that has been subjected to chromate treatment, for example, BHY (trade name, manufactured by Nippon Mining & Metals Co., Ltd.) having a thickness of about 18 μm, is laminated on the first insulating layer. The first insulating layer is cured by heating at about 180° C. for about 1 hour. In the rolled copper foil that has been subjected to chromate treatment, copper foil is removed by etching with a sulfuric acid/hydrogen peroxide-based etching solution, for example, SE-07 (trade name, manufactured by Mitsubishi Gas Chemical Company, Inc). A metal layer formed on a surface of the copper foil by the chromate treatment, e.g., an adhesion layer, is transferred onto the first insulating layer. The substrate including the first insulating layer is immersed in a Sn—Pd colloidal liquid, e.g., Cataposit 44 (trade name, manufactured by Rohm and Haas Company) at about 40° C. for about 5 minutes. The substrate is rinsed with water and dried at about 120° C. to form a separating layer including tin chloride and palladium chloride. A dry film resist composed of an acrylic resin, for example, RY3325 (trade name, thickness: about 25 manufactured by Hitachi Chemical Company, Ltd.), which will serve as a protective layer, is laminated on the layer containing tin chloride and palladium chloride. The protective layer is irradiated with light having a wavelength of about 365 nm at about 200 mJ/cm². Portions of the protective layer, the layer containing tin chloride and palladium chloride, the adhesion layer, and first insulating layer to be formed into a via are irradiated with carbon dioxide laser light to form a laser via having a diameter of about 40 μm. Plasma treatment is performed with a mixed gas of oxygen and CF₄ in a mixing ratio of about 95:5 to remove smears left on the bottom of the opening. The substrate is immersed in an amine-based separation liquid for a dry film, for example, RS-2000 (trade name, manufactured by Atotech Deutschland GmbH), to remove the protective layer. After the removal of the protective layer, the ten-point height of irregularities Rz of the first insulating layer may be about 0.2 μm. The separating layer arranged above an upper surface of the substrate has a thickness of about 5 nm to about 50 nm. Thus, the measured ten-point height of irregularities of the upper surface of the substrate may suggest the value of the first insulating layer below the separating layer. Electroless plating is performed with an electroless plating solution manufactured by Rohm and Haas Company, thereby forming a seed layer inside the opening and on the layer including tin chloride and palladium chloride, the seed layer including copper and having a thickness of about 0.3 μm. A resist pattern is formed on the seed layer by photolithography with a dry film resist, for example, RY3215 (trade name, manufactured by Hitachi Chemical Company, Ltd.) having a thickness of about 15 μm. The L/S of the resist pattern may be about 10 μm/about 10 μm. Electroplating is performed on the seed layer to form a conductive layer serving as the second wiring, the conductive layer having a thickness of about 15 μm and including copper. The resist pattern and the seed layer below the resist pattern are removed, thereby forming the second wiring. The L/S of the second wiring may be about 10 μm/about 10 μm. The second wiring may have a thickness of about 15 μm.

A process from the lamination of a first insulating layer on a substrate on which the first wiring including copper is provided to the transfer of an adhesion layer to the first insulating layer may be substantially identical or similar to the process illustrated in FIG. 2A. The substrate including the first insulating layer is immersed in an alkaline Pd colloidal liquid, for example, Activator 834 (trade name, manufactured by Atotech Deutschland GmbH) at about 30° C. for about 5 minutes. The substrate is rinsed with water and dried at about 120° C. to form a layer including palladium sulfate. As illustrated in FIGS. 2C to 2F, a protective layer is formed on a separating layer. Laser vias each having a diameter of about 40 μm are formed. Desmear treatment is performed to remove the protective layer. Electroless plating is performed with an electroless plating solution manufactured by Atotech Deutschland GmbH, thereby forming a seed layer inside the openings and on the layer including palladium sulfate, the seed layer including copper and having a thickness of about 0.5 μm. A resist pattern is formed on the seed layer by photolithography with a dry film resist, for example, RY3215 (trade name, manufactured by Hitachi Chemical Company, Ltd.) having a thickness of about 15 μm. The L/S of the resist pattern may be about 10 μm/about 10 μm. Electroplating is performed on the seed layer to form a conductive layer corresponding to the second wiring, the conductive layer having a thickness of about 15 μm and including copper. The resist pattern and the seed layer below the resist pattern are removed. The L/S of the second wiring may be about 10 μm/about 10 μm. The second wiring may have a thickness of about 15 μm.

Rolled copper foil that has been subjected to chromate treatment, for example, BHY (trade name, manufactured by Nippon Mining & Metals Co., Ltd.) is immersed in an about 1% by weight aqueous solution of a 2,4,6-trimercapto-1,3,5-triazine monosodium salt, for example, an aqueous solution of Santhiol N-1 (trade name, manufactured by Sankyo Kasei Co., Ltd). The rolled copper foil, BHY (trade name, manufactured by Nippon Mining & Metals Co., Ltd.), may have a thickness of about 18 μm and a surface roughness Rz of about 0.7 μm. The rolled copper foil is dried by baking at about 100° C. for about 30 minutes to complete triazinethiol treatment. A thermosetting epoxy resin to be used as a first insulating layer is laminated on a substrate including the first wiring. The rolled copper foil that has been subjected to triazinethiol treatment is laminated on the first insulating layer. The first insulating layer is cured by heating at about 180° C. for about 1 hour. The copper foil that has been subjected to chromate treatment and triazinethiol treatment is removed by etching with a sulfuric acid/hydrogen peroxide-based etching solution, for example, SE-07 (trade name, manufactured by Mitsubishi Gas Chemical Company, Inc). An adhesion layer including a compound layer composed of triazinethiol and a metal layer formed on a surface of the copper foil by chromate treatment is transferred onto the first insulating layer. The substrate including the first insulating layer is immersed in an alkaline Pd colloidal liquid, for example, Activator 834 (trade name, manufactured by Atotech Deutschland GmbH) at about 30° C. for about 5 minutes. The substrate is rinsed with water and dried at about 120° C. to form a separating layer including palladium sulfate. As illustrated in FIG. 2C, a protective layer is formed on the separating layer. Portions of the protective layer, the layer including palladium sulfate, the adhesion layer, and the first insulating layer to be formed into vias are irradiated with carbon dioxide laser light to form laser vias each having a diameter of about 40 μm. As illustrated in FIGS. 2D to 2F, desmear treatment is performed, and the protective layer is removed. Electroless plating is performed with an electroless plating solution manufactured by Atotech Deutschland GmbH, thereby forming a seed layer inside the openings and on the layer including palladium sulfate, the seed layer including copper and having a thickness of about 0.5 μm. A resist pattern is formed on the seed layer by photolithography with a dry film resist, for example, RY3215 (trade name, manufactured by Hitachi Chemical Company, Ltd.) having a thickness of about 15 μm. The L/S of the resist pattern may be about 10 μm/about 10 μm. Electroplating is performed on the seed layer to form a conductive layer corresponding to the second wiring, the conductive layer having a thickness of about 15 μm and including copper. The resist pattern and the seed layer below the resist pattern are removed to form the second wiring. The L/S of the second wiring may be about 10 μm/about 10 μm. The second wiring may have a thickness of about 15 μm.

Example embodiments of the present invention have now been described in accordance with the above advantages. It will be appreciated that these examples are merely illustrative of the invention. Many variations and modifications will be apparent to those skilled in the art.

1. A method of manufacturing a wiring board, comprising:
forming an insulating resin layer on a conductive layer;
forming a metal chloride or a metal sulfate on the insulating resin layer;
forming a protective layer on the metal chloride or the metal sulfate;
forming an exposed portion in the insulating resin layer, the metal chloride or the metal sulfate, and the protective layer so as to at least partially expose the conductive layer;
removing residues in the exposed portion;
removing the protective layer; and
forming a wiring on the insulating resin layer in which the protective layer has been removed.

2. The method according to claim 1,
wherein the metal chloride or the metal sulfate includes tin or palladium.

3. The method according to claim 1, further comprising:
forming an adhesion layer between the insulating resin layer and the metal chloride or between the insulating resin layer and the metal sulfate.

4. The method according to claim 1,
wherein the separating layer includes at least one metal layer including at least one metal selected from the group consisting of zinc, nickel, cobalt and chromium.

5. The method according to claim 1,
wherein the adhesion layer includes at least one compound layer including at least one compound selected from the group consisting of triazinethiol, a silane coupling agent, nitrobenzoic acid, and mercaptosulfonic acid.

6. The method according to claim 1,
wherein the protective layer includes an acrylic resin.

7. The method according to claim 1,
wherein the insulating resin layer includes an epoxy resin.

8. The method according to claim 1,
wherein dry etching is performed in an atmosphere including CF₄ or SF₆.

9. The method according to claim 1,
wherein wet etching is performed with a liquid including permanganate.

10. The method according to claim 1,
wherein the conductive layer includes copper.

11. The method according to claim 1,
wherein the protective layer is immersed in a separation liquid.

12. The method according to claim 11,
wherein the insulating resin layer is insoluble in the separation liquid,
the metal chloride or the metal sulfate is insoluble in the separation liquid, and
the protective layer is soluble in the separation liquid.

13. The method according to claim 1,
wherein the metal chloride or the metal sulfate is immersed in a separation liquid.

14. The method according to claim 13,
wherein the insulating resin layer is insoluble in the separation liquid, and
the metal chloride or the metal sulfate is soluble in the separation liquid.
